(19) United States
(12) Patent Application Publication
(10) Pub. No.: US 2026/0354048 A1
(43) Pub. Date: Nov. 5, 2026

(54) PHASE CHANGE MEMORY STRUCTURES AND MANUFACTURING METHODS

(71) Applicant: Taiwan Semiconductor Manufacturing Company, Ltd., Hsinchu (TW)

(72) Inventors: Chang-Chih Huang, Taichung (TW); Chih-Ren Hsieh, Changhua City (TW); Kuo-Pin Chang, Zhubei city (TW); Kuo-Ching Huang, Hsinchu City (TW)

(73) Assignee: Taiwan Semiconductor Manufacturing Company, Ltd., Hsinchu (TW)

(21) Appl. No.: 19/197,101

(22) Filed: May 2, 2025

(51) Int. Cl. H10N 70/00; H10B 63/10; H10N 70/20

(52) U.S. Cl. CPC H10N 70/8413; H10B 63/10; H10N 70/063; H10N 70/231; H10N 70/8828

(57) ABSTRACT

Semiconductor devices including phase change memory (PCM) memory cells and fabrication methods are disclosed. A PCM memory cell structure includes a bottom electrode, an enclosing portion of conductive material disposed within an interlayer dielectric layer, the enclosing portion of conductive material overlying the bottom electrode and laterally circumscribing a region of insulating material overlying the bottom electrode, a phase change material layer overlying the enclosing portion of conductive material and the region of insulating material, wherein the region of insulating material is disposed between the bottom electrode and the phase change material layer, a top electrode overlying the phase change material layer, and a conductive structure between the top electrode and the enclosing portion of conductive material to provide a conductive path between the top electrode and the bottom electrode through the enclosing portion of conductive material and the conductive structure.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon. The semiconductor industry continues to improve the integration density of various electronic components (e.g., transistors, diodes, resistors, capacitors, etc.) by continual reductions in minimum feature size, which allow more components to be integrated into a given area.

### BRIEF DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-12 are cross-sectional views and top views of an example phase-change material (PCM) memory cell structure in various phases of fabrication in accordance with various embodiments, wherein FIG. 11 is a top view corresponding to the state of the PCM memory cell structure after the fabrication processes described in the context of FIG. 4 and FIG. 12 is a top view corresponding to the state of the PCM memory cell structure depicted in FIG. 11 after the fabrication of an overlying conductive barrier layer in accordance with one or more embodiments.

FIGS. 13-15 are cross-sectional views of a PCM memory cell structure in various phases of fabrication in accordance with various embodiments;

FIGS. 16-21 are cross-sectional views and top views of an example PCM memory cell structure in various phases of fabrication in accordance with various embodiments, wherein FIG. 20 is a top view corresponding to the state of the PCM memory cell structure after the fabrication processes described in the context of FIG. 19 in accordance with one or more embodiments;

FIG. 22 is a flow chart of an example fabrication process for fabricating a PCM memory cell structure of a semiconductor device in accordance with various embodiments; and

FIGS. 23-25 are perspective views of a bottom electrode via (BEVA) heating structures and equivalent electrical circuit representation in accordance with various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting.

For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

It should be understood that, although the terms first, second, third etc. may be used herein to describe various elements, components, regions, layers, portions and/or sections, these elements, components, regions, layers, portions and/or sections should not be limited by these terms. These terms are only used to distinguish one element, component, region, layer, portion or section from another region, layer, or section. Thus, a first element, component, region, layer, portion, or section discussed below could be termed a second element, component, region, layer, portion, or section without departing from the teachings of the present disclosure.

Furthermore, spatially relative terms, such as “over”, “overlying”, “above”, “upper”, “top”, “under”, “underlying”, “below”, “lower”, “bottom”, and the like, may be used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When a spatially relative term, such as those listed above, is used to describe a first element with respect to a second element, the first element may be directly on the other element, or intervening elements or layers may be present.

In addition, the present disclosure may repeat reference numerals and/or letters in the various examples. This repetition is for the purpose of simplicity and clarity and does not in itself dictate a relationship between the various embodiments and/or configurations discussed.

It is noted that references in the specification to “one embodiment,” “an embodiment,” “an example embodiment,” “exemplary,” “example,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to affect such feature, structure, or characteristic in connection with other embodiments whether or not explicitly described.

In certain embodiments herein, a “material layer” is a layer that includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material; and a layer that is a “material” includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material. For example, certain embodiments, each of an aluminum layer and a layer of aluminum is a layer that is at least 50 wt. %, at least 60 wt. %, at least 75 wt. %, at least 90 wt. %, at least 95 wt. %, or at least 99 wt. % of aluminum.

It is to be understood that the phraseology or terminology herein is for the purpose of description and not of limitation, such that the terminology or phraseology of the present specification is to be interpreted by those skilled in relevant art(s) in light of the teachings herein.

The following disclosure provides many different embodiments, or examples, for implementing different features of the disclosed subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. Throughout the description herein, unless otherwise specified, the same reference numeral in different figures refers to the same or similar component formed by a same or similar method using a same or similar material(s).

Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

As used herein, a “layer” is a region, such as an area comprising arbitrary boundaries, and does not necessarily comprise a uniform thickness. For example, a layer can be a region comprising at least some variation in thickness.

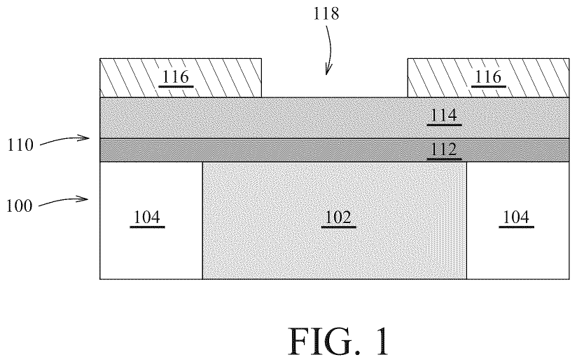

FIGS. 1-10 illustrate, in cross-section, one or more methods for fabricating a phase-change material (PCM) memory cell structure 1000 that includes a heating structure 400 (or heater) fabricated in connection with a bottom electrode via (BEVA) fabrication process (alternatively referred to herein as a BEVA heater) overlying a lower interconnect layer 100 for routing electrical signals that includes a bottom electrode portion 102 of conductive material, such as copper or another metal material, that is formed within a voided region between surrounding portions 104 of insulating material and functions as a bottom electrode of the PCM memory cell. A PCM memory cell is configurable to store a data state based upon a phase of a PCM region, which either store a first data state (e.g., a logical or binary “0”) when the PCM region has a crystalline phase corresponding to a low resistance state and a second data state (e.g., a logical or binary “1”) when the PCM region has an amorphous phase corresponding to a high resistance state, or vice versa.

Various steps in the manufacture of semiconductor devices are well known and so, in the interest of brevity, many conventional steps will only be mentioned briefly herein or will be omitted entirely without providing the well-known process details. In this regard, in exemplary implementations, the lower interconnect layer 100 and the PCM memory cell structure 1000 are fabricated on or overlying a substrate, which may be any sort of bulk substrate (e.g., a bulk silicon substrate), silicon-on-insulator (SOI) substrate, or another suitable substrate, and the lower interconnect layer 100 may be fabricated during one or more back end of line (BEOL) process stages after transistors or other electronic circuitry have been fabricated on the semiconductor substrate.

Referring to FIG. 1, to fabricate a BEVA heater of the PCM memory cell structure 1000, a semiconductor device fabrication process forms an interconnect dielectric structure 110 on or overlying the metal interconnect layer 100 as part of a BEVA process stage. In practice, the interconnect dielectric structure 110 may include one or more interlayer dielectric (ILD) layers (e.g., an oxide, a low-k dielectric material, or the like) and/or dielectric protection layers (e.g., comprising silicon carbide, silicon nitride, or the like). In this regard, FIG. 1 depicts an interconnect dielectric structure 110 including a dielectric protection layer 112 of silicon carbide deposited or otherwise formed on or overlying the metal interconnect layer 100 to a thickness in the range of about 20 nanometers (nm) (or 200 Å) to about 30 nm (300 Å), and an ILD layer 114 of oxide material is deposited or otherwise formed on or overlying the dielectric protection layer 112 to a thickness in the range of about 30 nm (300 Å) to about 70 nm (700 Å).

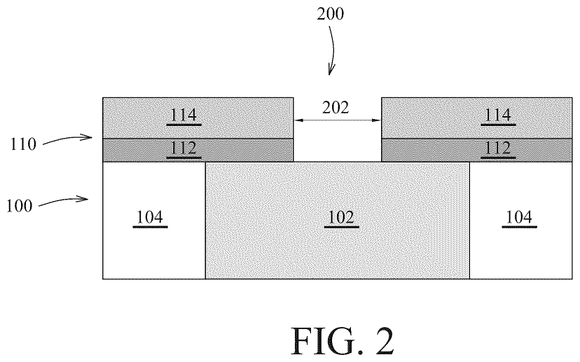

Referring to FIGS. 1-2, after forming the interconnect dielectric structure 110, the BEVA process stage of the semiconductor device fabrication process continues by forming a layer 116 of an antireflective coating (ARC) material overlying the ILD layer 114 of the interconnect dielectric structure 110, for example, by conformally depositing a layer of nitrogen-free anti-reflection coating (NFARC) material (e.g., such as silicon oxide, silicon oxygen carbide, or plasma enhanced chemical vapor deposited (PECVD) silicon oxide) on or overlying upper surface of the ILD layer 114 to a thickness in the range of about 340 Å. The BEVA process stage of the semiconductor device fabrication process continues by patterning and anisotropically (or directionally) etching the interconnect dielectric structure 110 using suitable photolithography and etching techniques to define a voided region 118 within the ARC layer 116.

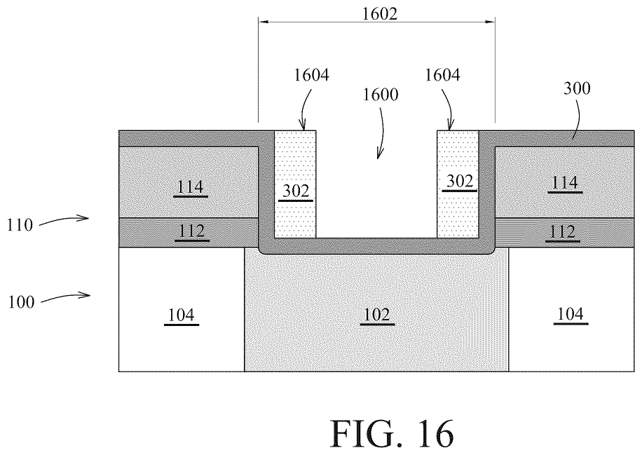

Referring to FIG. 2, after patterning the hard mask layer 116, the fabrication process continues by anisotropically etching the layers 112, 114 of the interconnect dielectric structure 110 using the remaining portions of the ARC layer 116 as an etch mask to form a corresponding voided region 200 within the interconnect dielectric structure 110. In this regard, the interconnect dielectric structure 110 is anisotropically etched to a depth that is greater than or equal to a combined thickness of the layers 112, 114 to expose the upper surface of the bottom electrode portion 102 underlying the voided region 200. In one or more implementations, the width 202 of the voided region 200 is about 60 nm; that said, in other implementations, the width 202 may vary depending on the configuration of the BEVA heating structure, as described in greater detail below in the context of FIGS. 16-21. After forming the voided region 200, the remaining portions of the ARC layer 116 are removed from the upper surface of the semiconductor substrate as depicted in FIG. 2.

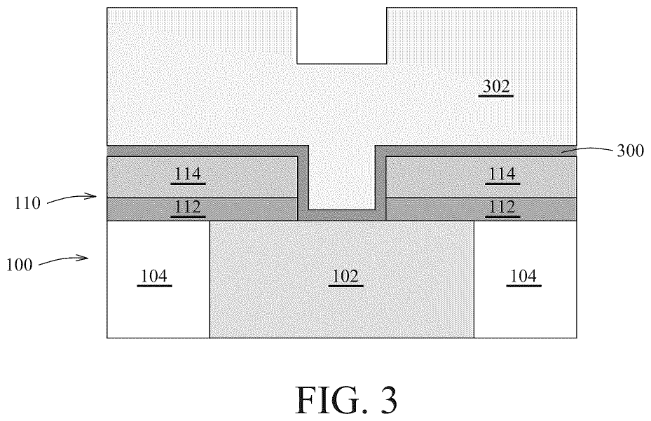

Referring to FIG. 3, after forming the voided region 200, the semiconductor device fabrication process continues by forming a layer 300 of a conductive barrier material overlying the semiconductor substrate, for example, by conformally depositing a layer of tantalum nitride (TaN) or another suitable conductive barrier material (e.g., copper) to a thickness in the range of about 2 nm to about 20 nm on the exposed surface of the bottom electrode portion 102 and the exposed surfaces of the layers 112, 114 of the interconnect dielectric structure 110, including the vertical sidewall surfaces and bottom surfaces defining boundaries of the voided region 200. After forming the conductive barrier layer 300, the semiconductor device fabrication process continues by forming a layer 302 of an insulating material overlying the semiconductor substrate, for example, by conformally depositing a layer of an oxide material or another suitable insulating material on and overlying the conductive barrier layer 300 to a thickness that is greater than or equal to the depth of the voided region 200 or the thickness of the interconnect dielectric structure 110 (e.g., the combined thickness of the layers 112, 114) to achieve at least a flush fill or overfill of the voided region 200. In exemplary implementations, the insulating layer 302 is realized as a low-k dielectric material having a dielectric constant less than silicon dioxide, such as, for example, silicon carbonitride (SiCN) or silicon carbonate.

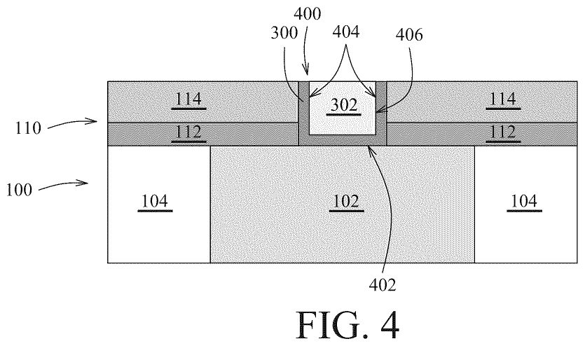

Referring to FIG. 4, the semiconductor device fabrication process continues by planarizing by a chemical mechanical planarization (CMP) process or another suitable planarization process (which may be part of the BEVA process stage) until an upper surface of the ILD layer 114 is reached, thereby removing portions of the conductive barrier layer 300 and the insulating layer 302 from the planar surfaces concurrent to defining BEVAs on other regions of the semiconductor substrate. The remaining conductive barrier material portions 402,404 and the remaining insulating material portion 406 cooperatively define part of a BEVA heating structure 400 (or BEVA heater) associated with the PCM memory cell structure 1000, as described in greater detail below. The remaining sidewall portions 404 of the conductive barrier layer 300 formed on the exposed interior vertical surfaces of the voided region 200 define a conductive enclosing portion (or conductive ring portion) that laterally encompasses, encloses or otherwise circumscribes a central or interior portion 406 of the remaining insulating layer 302 which overlies a planar or lateral bottom portion 402 of the conductive barrier layer 300 formed on the exposed upper surface of the bottom electrode portion 102. In this manner, the remaining conductive barrier material portions 402, 404 provide a conductive path for electrical current flow vertically through the interconnect dielectric structure 110 about the periphery of the insulating material portion 406, while the remaining insulating material portion 406 inhibits electrical current flow vertically, thereby increasing the effective resistance of the BEVA heating structure 400 vertically.

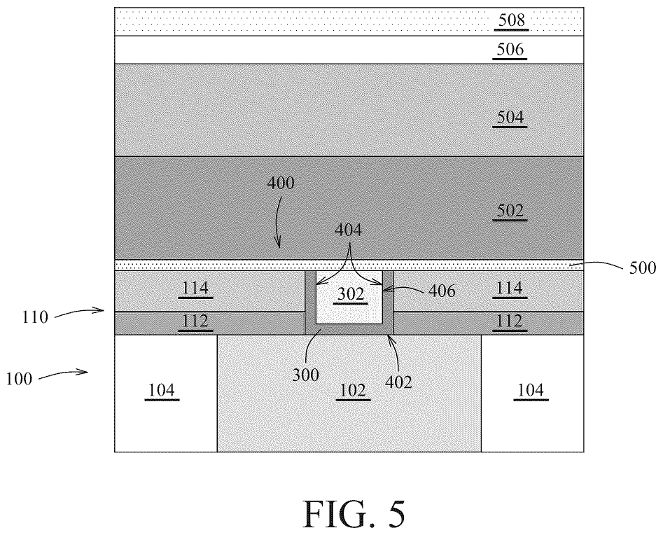

Referring to FIG. 5, the semiconductor device fabrication process continues by forming a top liner layer 500 of conductive barrier material overlying the semiconductor substrate, for example, by conformally depositing a layer of tantalum nitride (TaN) or another suitable conductive barrier material overlying the exposed planar upper surfaces of the ILD layer 114 and the remaining BEVA heating structure portions 402,404, 406 formed within the voided region 200 in a similar manner as described above in the context of conductive barrier layer 300 (e.g., to a thickness in the range of about 2 nm to about 20 nm).

Thereafter, the semiconductor device fabrication process continues by forming a layer 502 of a PCM on and overlying the top liner conductive barrier layer 500. For example, the PCM layer 502 may be realized as Ge₂Sb₂Te₅ (GST), Ge—In—Sb—Te (GIST), Ag—In—Sb—Te (AIST), or some other chalcogenide compound deposited or grown on and in direct contact with the upper surface of the top liner conductive barrier layer 500 using chemical vapor deposition (CVD) or another suitable deposition or growth process to a thickness in the range of about 20 nm to about 100 nm.

After forming the PCM layer 502, the semiconductor device fabrication process continues by forming an electrode layer 504 of conductive material (which may alternatively be referred to as a top electrode (TE) layer) on and overlying the PCM layer 502, for example, by conformally depositing a layer of tungsten, copper, aluminum copper, carbon, titanium nitride or another suitable conductive material on the upper surface of the PCM layer 502 to a thickness in the range of about 10 nm to about 100 nm. Thereafter, the semiconductor device fabrication process continues by forming a first layer 506 of a hard mask material, such as a silicon nitride material, a silicon oxide material or the like, on and overlying the electrode layer 504, and forming a second layer 508 of a hard mask material on and overlying the first hard mask layer 506. In this regard, the hard mask layers 506, 508 may be realized as different materials having different etch selectivity to provide a mechanism for stopping etch processes when forming contacts, vias, or other structures.

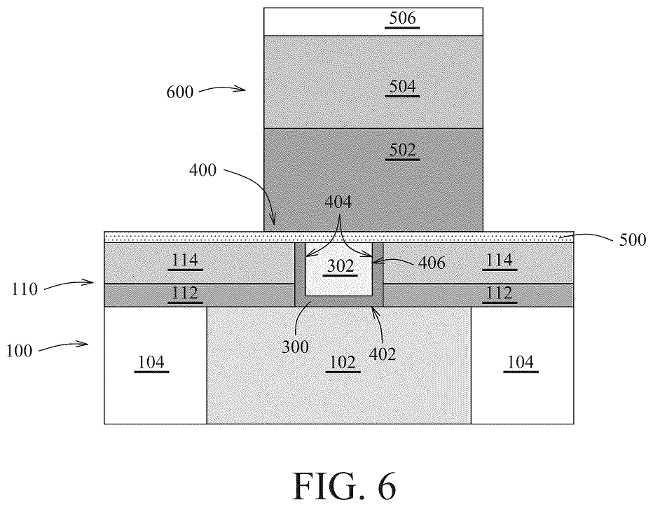

Referring now to FIG. 6, the semiconductor device fabrication process continues by patterning the upper hard mask layer 508 to define an etch mask that overlies at least the BEVA heating structure portions 402,404, 406 before anisotropically (or directionally) etching the exposed portions of the PCM layer 502, the electrode layer 504 and the hard mask layer 506 and stopping on the conductive barrier layer 500 to define an intermediate PCM structure 600 overlying the BEVA heating structure portions 402,404, 406. After defining the intermediate PCM structure 600, any remaining portions of the upper hard mask layer 508 are removed, resulting in the state depicted in FIG. 6.

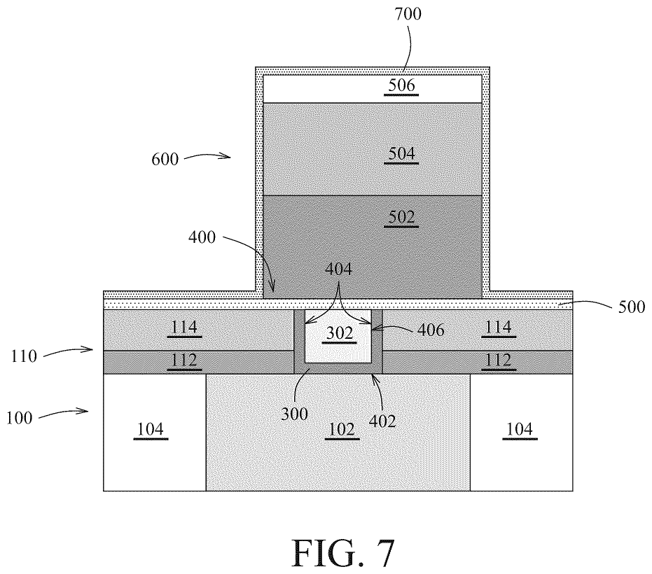

Referring now to FIG. 7, after defining the intermediate PCM structure 600, the semiconductor device fabrication process continues by forming another layer 700 of conductive barrier material overlying the semiconductor substrate, for example, by conformally depositing a layer of tantalum nitride (TaN) or another suitable conductive barrier material overlying the exposed surfaces of the conductive barrier layer 500 and the intermediate PCM structure 600 in a similar manner as described above in the context of conductive barrier layer 300 (e.g., to a thickness in the range of about 2 nm to about 20 nm).

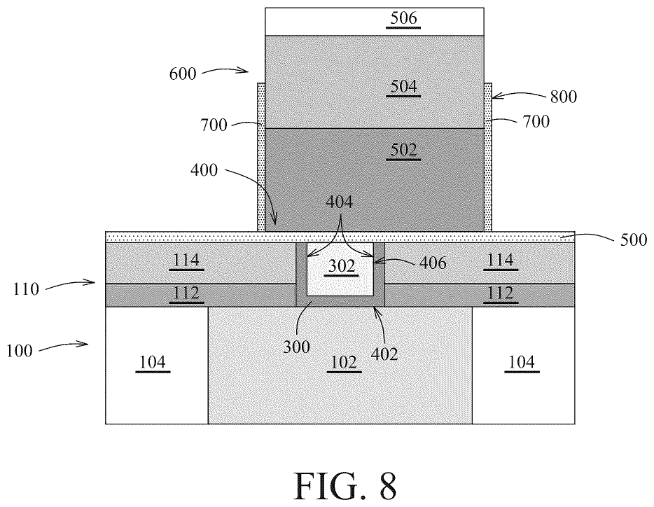

Referring to FIG. 8, the semiconductor device fabrication process continues by anisotropically etching the conductive barrier layer 700 to form spacers 800 of the conductive barrier material of the conductive barrier layer 700 along the vertical sidewalls of the intermediate PCM structure 600 while removing the exposed portion of the conductive barrier layer 700 from the upper surface of the intermediate PCM structure 600. The remaining spacers 800 of conductive barrier material contact the lateral surface of the top electrode layer 504 and the underlying barrier layer 500 provide a conductive path for electrical current flow between the remaining portion of the electrode layer 504, that is, between the top electrode of the PCM memory cell structure 1000 and the underlying conductive barrier layer 500 that underlies the remaining portion of the PCM layer 502. In this regard, the electrical resistance of the PCM layer 502 in an amorphous state is greater than the conductive barrier layer 700, such that an input voltage or current applied to the top electrode layer 504 results in current flow that bypasses the PCM layer 502 to the underlying barrier layer 500 and BEVA heater 400 through the sidewall spacer 800. The width of the spacers 800 corresponds to the thickness of the conductive barrier layer 700 and may range from about 2 nm to about 20 nm.

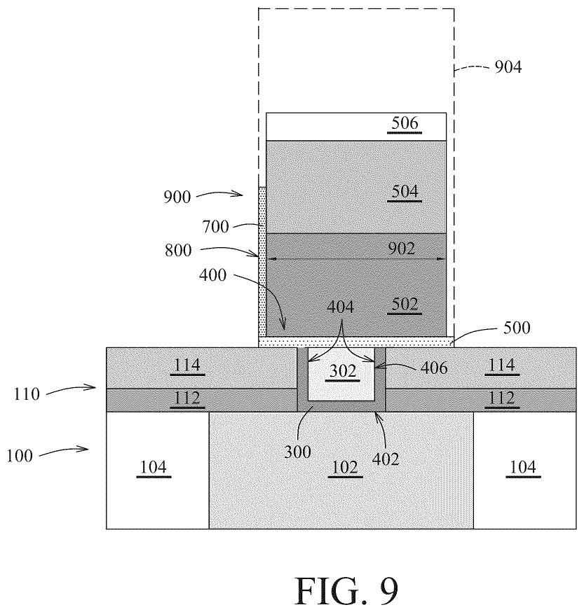

Referring to FIG. 9, after forming the sidewall spacers 800 of conductive barrier material, the semiconductor device fabrication process continues by forming a layer 904 of photoresist or other suitable etch mask material overlying the intermediate PCM structure 600, patterning the photoresist layer 904 to expose at least a portion of the intermediate PCM structure 600 that does not overlie the remaining BEVA heating structure portions 402,404, 406 formed within the voided region 200, and anisotropically etching the exposed portions of the layers 502, 504, 506 of the intermediate PCM structure 600 to remove the exposed portions of the intermediate PCM structure 600 to obtain the PCM structure 900 overlying the BEVA heating structure portions 402,404, 406 that includes a single spacer 800 of conductive barrier material. In this regard, the width 902 of the resulting PCM structure 900 is less than the width of the intermediate PCM structure 600 but greater than the width 202 of the voided region 200 and the BEVA heating structure portions 402,404, 406 formed therein. In some embodiments, the anisotropic etching is performed using the conductive barrier layer 500 as an etch stop layer to mitigate formation of a recess into the ILD layer 114.

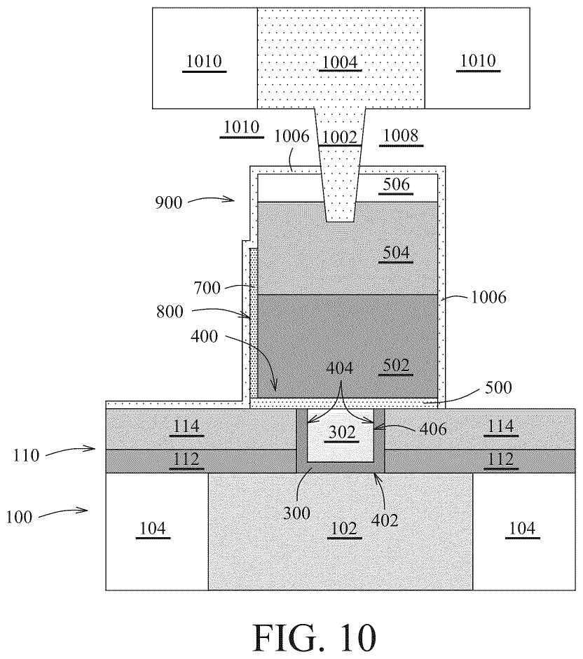

Referring to FIG. 10, after forming the PCM structure 900, the semiconductor device fabrication process continues by removing the remaining portions of the photoresist layer 904 and performing a top electrode via (TEVA) fabrication process stage to form a TEVA structure 1002 providing a vertical interconnection between the top electrode layer 504 of the PCM structure 900 and an interconnecting top electrode portion 1004 of metal material in an overlying metal interconnect layer. In an exemplary embodiment, the TEVA fabrication process stage includes forming one or more dielectric protection layers 1006 overlying the PCM structure 900 and forming one or more ILD layers 1008 overlying the dielectric protection layers 1006. After forming the ILD layer 1008, the TEVA fabrication process stage continues by planarizing the upper surface of the ILD layer 1008, forming an etch mask included a voided region corresponding to the conductive via structure 1002 overlying the PCM structure 900, and anisotropically etching the ILD layer 1008 using the etch mask to a depth that is greater than or equal to a combined thickness of the remaining portion of the hard mask layer 506 and the portion of the ILD layer 1008 overlying the PCM structure 900 to expose at least a portion of the TE layer 504 of the PCM structure 900. Thereafter, the etch mask is removed and a layer of conductive via material is deposited or otherwise formed on and overlying the semiconductor substrate to a thickness that is greater than or equal to a depth of the voided region, resulting in the conductive via structure 1002 that extends vertically from the TE layer 504 of the PCM structure 900 through the overlying ILD layer 1008.

After fabrication of the TEVA structure 1002 overlying the PCM structure 900, the semiconductor device fabrication process continues by forming an overlying metal interconnect layer including an interconnecting portion 1004 of metal or other conductive material on and overlying the TEVA structure 1002 within an overlying ILD layer 1010 to provide an electrical interconnection to/from the TE layer 504 of the PCM structure 900 through the conductive TEVA structure 1002. Thereafter, additional BEOL process stages may be performed to complete fabrication of an integrated circuit or other semiconductor device including the PCM memory cell structure 1000, which are not germane to this disclosure.

To store or program the PCM memory cell structure 1000 to store a particular data state, an input current (or voltage) is applied to the TE layer 504 of the PCM structure 900 that causes the BEVA heating structure including the underlying BEVA portions 402,404, 406 to generate heat by virtue of the resistivity and thermal conductivity of the respective material layers 300, 302, which, in turn, causes the phase of the PCM layer 502 to change between a crystalline phase corresponding to a low resistance state and an amorphous phase corresponding to a high resistance state. To program the PCM layer 502 for the lower resistance state, a programming input current signal is applied that has a magnitude and a corresponding duration of time that causes the temperature of the PCM layer 502 to meet or exceed a crystalline phase temperature threshold that results in the material of the PCM layer 502 transitioning from a disordered amorphous phase to an ordered crystalline phase having a lower resistivity while preventing the temperature of the PCM layer 502 from exceeding a melting temperature threshold that is greater than the crystalline phase temperature threshold. On the other hand, to reset the PCM memory cell structure 1000 and return the PCM layer 502 to a higher resistance state, a reset input current signal is applied that has a greater magnitude than the programming input current signal but a shorter duration than the programming input current signal to cause the temperature of the PCM layer 502 to temporarily exceed the melting temperature threshold before rapidly quenching the PCM layer 502 to cause the PCM layer 502 to transition from the crystalline phase to the disordered amorphous phase having higher resistance.

By virtue of the fabrication process described in connection with FIGS. 1-10, the BEVA heating structure includes peripheral conductive portions 404 of the barrier material layer 300 that laterally surround, enclose or otherwise encompass an interior or central portion 406 of the insulating material layer 302, resulting in the BEVA heating structure 400 having a laterally-enclosing cross-section with a relatively high resistance interior portion 406 encompassed by lower resistance peripheral portions 404 that effectively provide lower electrical resistance parallel to the higher resistance interior portion 406. By virtue of the vertical length (or height) of the laterally-enclosing sidewall portions 404 (e.g., about 50 nm to about 100 nm corresponding to the thickness of the dielectric structure 110) being greater than the lateral width (e.g., about 2 nm to about 20 nm corresponding to the thickness of the conductive barrier layer 300), the effective resistance (R) of the BEVA heating structure 400 is increased in accordance with the equation

$$R = \frac{l}{w} \times ρ ,$$

where l is the length of the laterally-enclosing sidewall portions 404 in a vertical direction, w is the width of the laterally-enclosing sidewall portions 404 in a lateral direction, and ρ is the resistivity of the conductive barrier material.

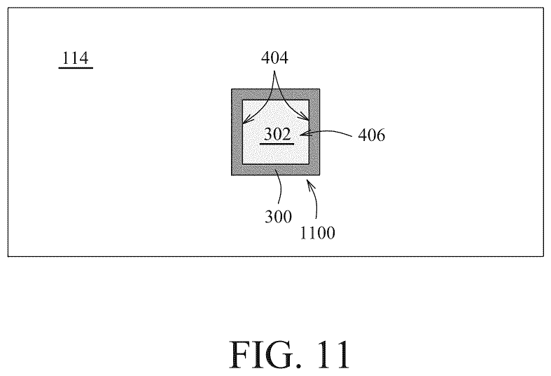

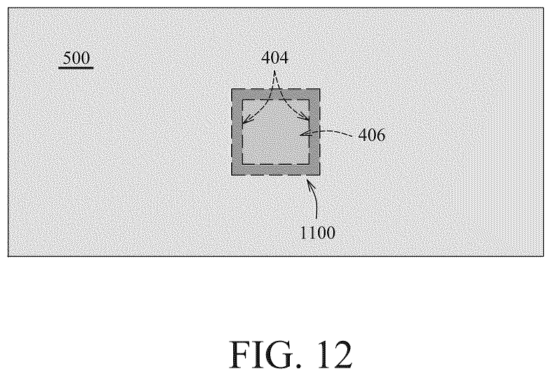

FIG. 11 depicts a top view of the PCM memory cell structure region of the semiconductor substrate showing the laterally-enclosing conductive structure 1100 formed by the laterally-enclosing sidewall portions 404 after planarization of the conductive barrier layer 300 and the insulating material layer 302 (FIG. 4), and FIG. 12 depicts a top view of the PCM memory cell structure region of the semiconductor substrate after formation of the conductive barrier layer 500 (FIG. 5). The higher resistance interior portion 406 of insulating material layer 302 causes vertical current flow through the BEVA heating structure to be laterally distributed about the peripheral portions 404 of conductive barrier material layer 300, thereby distributing current flow laterally about the remaining portion of the conductive barrier layer 500 underlying the PCM structure 900, which, in turn, laterally distributes heat more evenly across the PCM structure 900 underneath the PCM layer 502, thereby heating the PCM layer 502 more evenly. It should be noted that although FIGS. 11-12 depict the laterally-enclosing conductive structure 1100 formed by laterally-enclosing sidewall portions 404 as having a substantially rectangular or substantially circular cross-section, in alternative embodiments, the laterally-enclosing conductive structure 1100 may have a substantially circular cross-section, a substantially annular cross-section, a substantially ringlike, a substantially elliptical cross-section, or any other suitable geometric shape or configuration. Accordingly, the subject matter described herein is not limited to any particular shape or cross-section of the laterally-enclosing conductive structure 1100. That said, for purposes of explanation, but without limitation, the laterally-enclosing conductive structure 1100 and/or the laterally-enclosing sidewall portions 404 may alternatively be referred to herein as a conductive ring, a conductive ring portion (or a variant thereof).

Increasing the effective resistance of the BEVA heating structure through the use of an interior portion 406 of the insulating material of layer 302 combined with a higher resistance conductive barrier material of layer 300 such as tantalum nitride (TaN) (which also has relatively lower thermal conductivity) relative to a BEVA heating structure using titanium nitride (TiN) or other conductive BEVA material improves the electrical and thermal efficiency of the BEVA heating structure by laterally distributing the current flow more evenly and more effectively increasing the temperature of the PCM layer 502 for the same level of input electrical current, thereby allowing the PCM layer 502 to be programmed or reset with reduced input power. For example, the effective resistance of a BEVA heating structure vertically between TE and BE of a PCM memory cell structure that includes a lower resistance material, such as TiN, for the interior of the BEVA heating structure is effectively dictated by the resistance of the interior material, whereas the effective resistance of the PCM memory cell structure 1000 including BEVA heating structure depicted in FIGS. 1-12 vertically between the TE metal portion 1004 and the BE metal portion 102 is effectively dictated by the resistance of the peripheral portions 402,404 of the barrier material layer 300, which has a higher resistance than TiN.

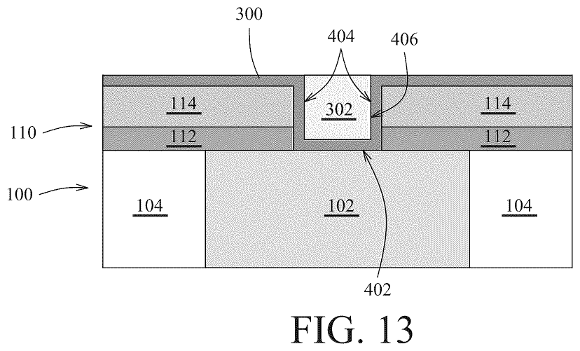

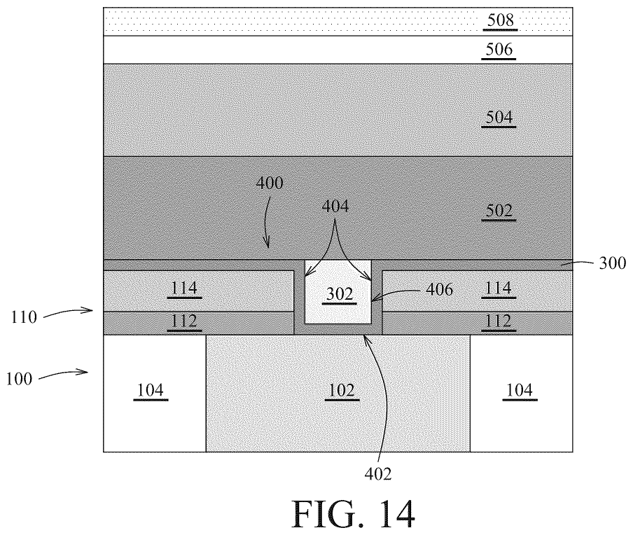

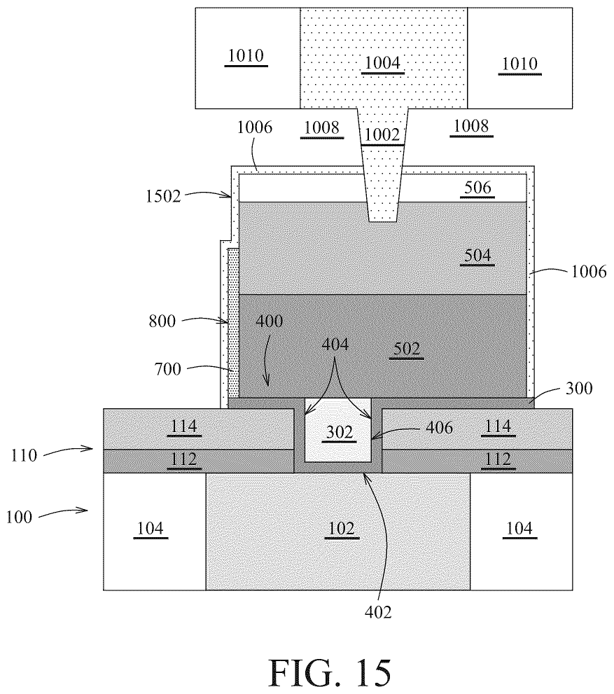

Referring to FIGS. 13-15, with continued reference to FIGS. 1-3 and 5-10, in one or more alternative embodiments, after forming the conductive barrier layer 300 and the insulating layer 302 (FIG. 3), an alternative semiconductor device fabrication process continues by planarizing the insulating layer 302 by a CMP process or another suitable planarization process until an upper surface of the conductive barrier layer 300 is reached by stopping the CMP process when the upper surface of the conductive barrier layer 300 is reached, as depicted in FIG. 13. Thereafter, the alternative semiconductor device fabrication process continues by forming the PCM layer 502 on and overlying the conductive barrier layer 300 and the remaining interior portion 406 of the insulating layer 302 without forming a second conductive barrier layer 500 prior to formation of the PCM layer 502 as depicted in FIG. 14. After forming the PCM layer 502, the semiconductor device fabrication process continues by forming the TE layer 504 and masking layers 506, 508 on and overlying the PCM layer 502 in a similar manner as described above in the context of FIG. 5, before proceeding with fabrication of a PCM structure 900 in a similar manner as described above in the context of FIGS. 6-10, resulting in the PCM memory cell structure 1500 depicted in FIG. 15.

By virtue of the alternative semiconductor device fabrication process eliminating the step of forming a second conductive barrier layer 500 underlying the PCM layer 502, the effective resistance of the BEVA heating in the PCM memory cell structure 1500 is increased by increasing the effective resistance of the lateral area underneath the PCM layer 502 by virtue of the remaining interior portion 406 of the insulating layer 302 decreasing the percentage of the lateral area underlying the PCM structure 1502 that includes conductive barrier material layer 300 for lateral current distribution.

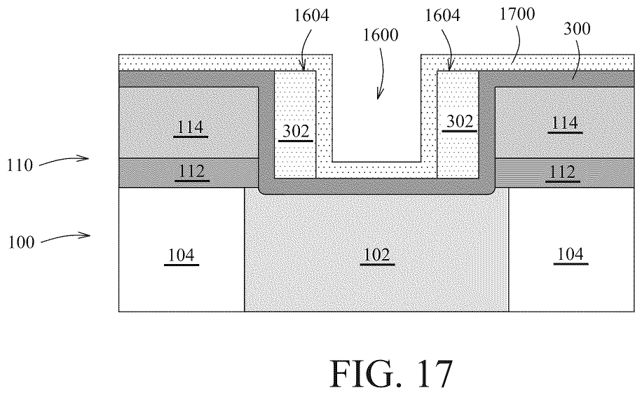

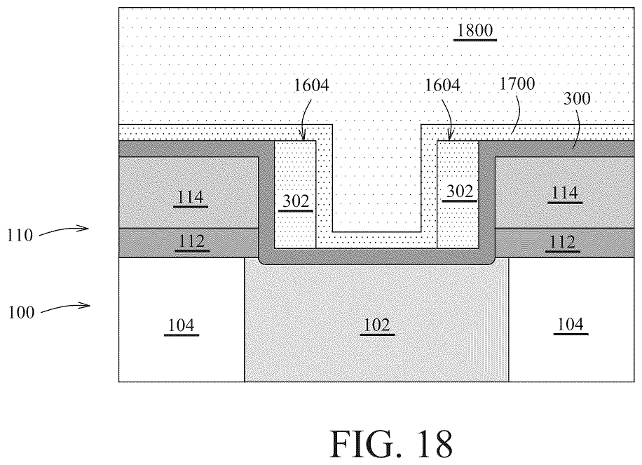

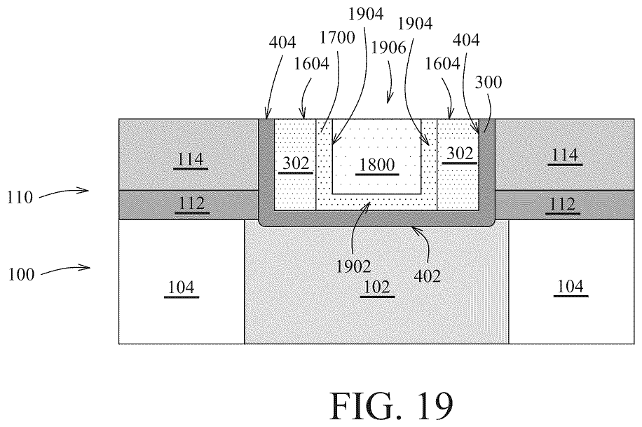

Referring to FIGS. 16-21, with reference to FIGS. 1-2, in one or more alternative embodiments, the fabrication process patterns the hard mask layer 116 to define a voided region 1600 having a larger lateral width 1602 prior to forming the first conductive barrier layer 300 and the first insulating layer 302 overlying the semiconductor substrate. For example, the width 1602 may be in the range of about 100 nm, or about 2 times the width 202 of the voided region 200 for the embodiments described above in connection with FIGS. 1-15. After forming the layers 300, 302, the alternative fabrication process continues by anisotropically etching the first insulating layer 302 and stopping on the conductive barrier layer 300 to define spacers 1604 along the vertical sidewalls of the voided region 1600. The fabrication process continues by forming a second conductive barrier layer 1700 overlying the semiconductor substrate as depicted in FIG. 17 before forming a second insulating layer 1800 to a thickness that is greater than or equal to the depth of the voided region 1600 as depicted in FIG. 18. After forming the second insulating layer 1800, the fabrication process planarizes the semiconductor substrate by a CMP process or another suitable planarization process until an upper surface of the ILD layer 114 is reached, thereby removing portions of the conductive barrier layers 300, 1700 and the insulating layer 1800 from the upper surface of the semiconductor substrate, as depicted in FIG. 19.

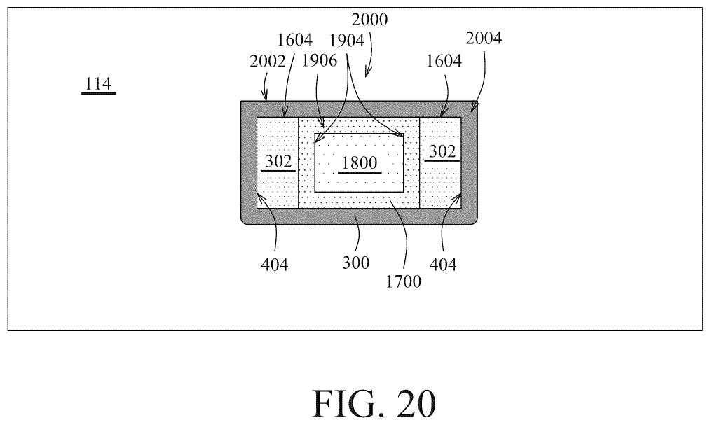

FIG. 20 is a top view of the state of the semiconductor substrate depicted in FIG. 19 after planarization of the second insulating layer 1800. The BEVA heating structure includes a central or interior ring 2000 defined by the remaining sidewall portions 1904 of the second conductive barrier layer 1700 circumscribing the remaining interior portion 1906 of the second insulating layer 1800 overlying the bottom portion 1902 of the second conductive barrier layer 1700, with peripheral rings 2002, 2004 adjacent to the interior ring 2000 corresponding to the respective sidewall spacers 1604 of insulating layer 302 that are defined by the remaining sidewall portions 404 of the first conductive barrier layer 300 and the remaining sidewall portions 1904 of the second conductive barrier layer 1700 between interior insulating portion 1906 and the respective sidewall spacer 1604. In this regard, it should be noted that while the embodiment shown in FIGS. 19-20 includes three rings 2000, 2002, 2004 of conductive barrier material laterally circumscribing respective portions of insulating layers 302, 1800, in alternative implementations, the semiconductor fabrication process may repeat the fabrication process steps described in the context of FIGS. 16-19 to form any number of additional rings of conductive barrier material laterally circumscribing additional portions of insulating material. Accordingly, the subject matter described herein is not limited to any particular size, shape or number of rings associated with the BEVA heating structure.

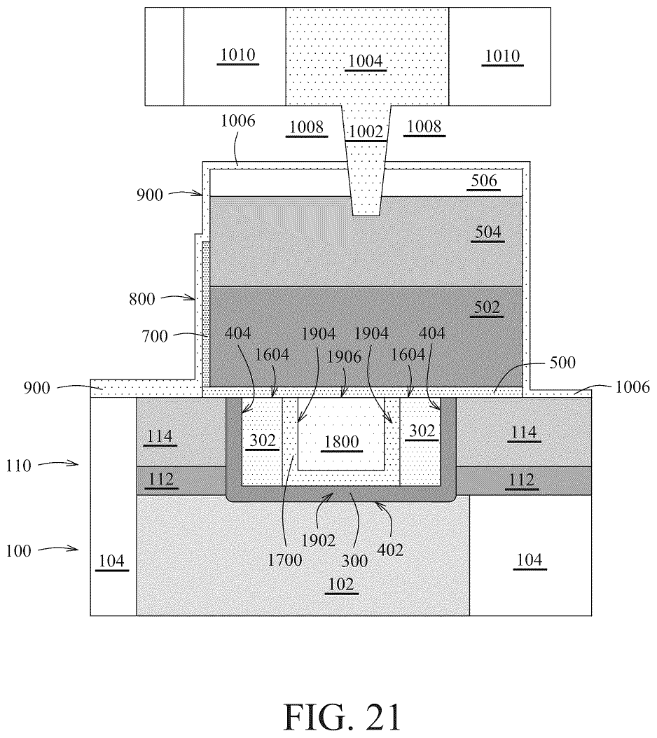

Referring to FIG. 21, after forming multiple BEVA heater rings 2000, 2002, 2004, the fabrication process proceeds in a similar manner as described above in the context of FIGS. 5-10 to form a PCM structure 900 overlying the BEVA heating structure comprised of the rings 2000, 2002, 2004 of conductive barrier layers 300, 1700 and interior portions 1604, 1904 of insulating material layers 302, 1800 and the overlying portion of conductive barrier layer 500, and thereafter form a TEVA structure 1002 providing a vertical interconnection between the top electrode layer 504 of the PCM structure 900 and an interconnecting portion 1004 of metal material in an overlying metal interconnect layer. By virtue of the additional rings 2000, 2002, 2004 in the BEVA heating structure, the resulting PCM memory cell structure 2100 depicted in FIG. 21 achieves reduced resistance relative to the PCM memory cell structure 1000 depicted in FIG. 10 by virtue of the additional rings 2000, 2002, 2004 providing additional parallel paths for current flow vertically through the BEVA heating structure while more uniformly distributing heat laterally across the PCM layer 502 by virtue of the increased lateral area of the BEVA heating structure resulting from increasing the width 1602 of the voided region 1600 for the BEVA heating structure.

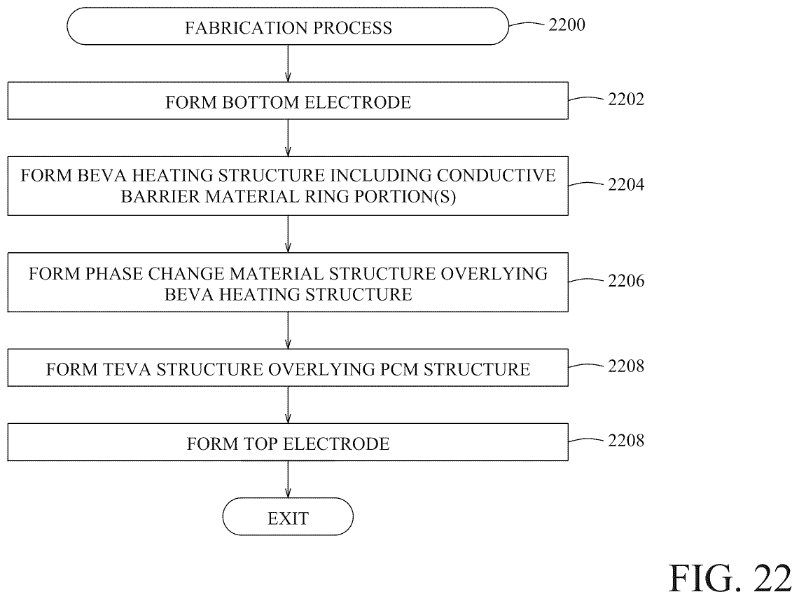

FIG. 22 depicts an exemplary embodiment of a fabrication process 2200 suitable for use to fabricate PCM memory cell structure of a semiconductor device as part of one or more BEOL process stages. Referring to FIG. 22 with continued reference to FIGS. 1-10, the fabrication process 2200 begins at 2202 by forming a bottom electrode of conductive material on or overlying a semiconductor substrate The fabrication process 2200 continues at 2204 by forming a BEVA heating structure including one or more conductive barrier material ring portions overlying the bottom electrode. As described above, in exemplary embodiments, the fabrication process forms a voided region 200 within an interlayer dielectric layer 114 overlying at least a portion of a bottom electrode 102 of conductive material on a semiconductor substrate, conformally depositing a conductive barrier layer 300 overlying the interlayer dielectric layer 114 and the portion of the bottom electrode 102 within the voided region 200, and conformally depositing an insulating layer 302 overlying the conductive barrier layer 300. The resulting BEVA heating structure 400 overlies at least a portion of the bottom electrode 102 within the ILD layer 114 overlying the interconnect layer 100, where the BEVA heating structure 400 includes a bottom portion 402 of conductive barrier material overlying and contacting at least a portion of the bottom electrode 102 underlying the voided region 200, a ring portion 404 of the conductive barrier material within the voided region 200 overlying the bottom portion 402 of the conductive barrier material, and an interior portion 406 of an insulating material overlying the bottom portion 402 of the conductive barrier material such that the ring portion 404 laterally circumscribes the interior portion 406.

The fabrication process 2200 continues by forming a PCM structure overlying the BEVA heating structure at 2206. For example, the PCM structure 900 is formed overlying at least the ring portion 404 of the BEVA heating structure 400 and includes at least a PCM layer 502 overlying the BEVA structure 400 and a top electrode layer 504 overlying the PCM layer 502. Additionally, the PCM structure 900 is configured to provide a conductive path between the top electrode layer 504 and the ring portion 404 through a sidewall spacer 800 of conductive barrier material.

The fabrication process 2200 completes fabrication of a PCM memory cell structure by forming a TEVA structure overlying the PCM structure at 2208 and forming a top electrode overlying the TEVA structure at 2210 such that the TEVA structure provides a vertical conductive path between the top electrode and the top electrode layer of the PCM structure.

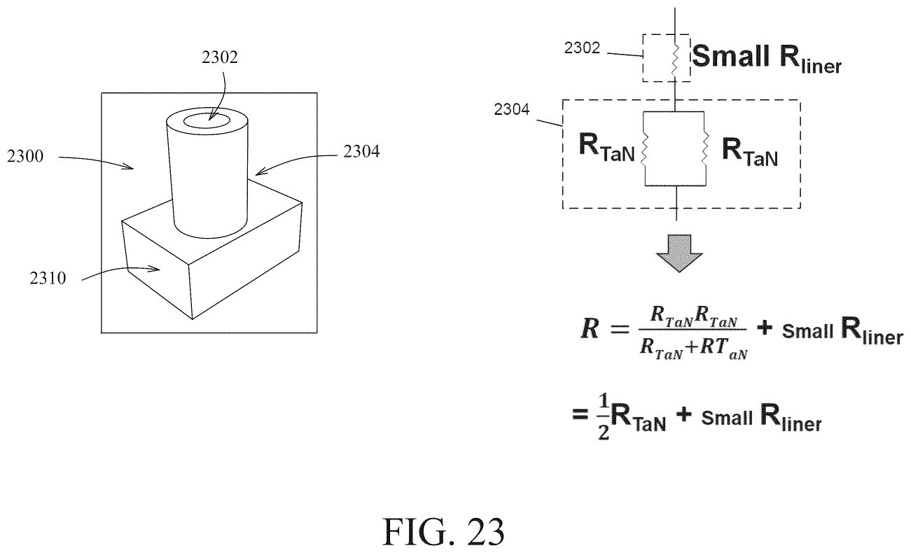

FIG. 23 depicts a perspective view of an exemplary BEVA heating structure 2300 having a substantially cylindrical shape with a substantially annular, circular or ringlike cross-section of vertical sidewall portions 2304 of conductive barrier material overlying a bottom electrode 2310 with a substantially planar top liner portion 2302 of conductive barrier material (e.g., conductive barrier layer 500) corresponding to the fabrication process of FIGS. 1-10 and a corresponding equivalent resistance of the resulting BEVA heating structure 2300. By virtue of the relatively low ratio of the length to width of the liner portion 2302 underlying the PCM structure, the effective resistance of the liner portion 2302 between the conductive structure 800 and the vertical sidewall portions 2304 is relatively small, resulting in the effective resistance of the BEVA heating structure 2300 being dictated by the vertical sidewall portions 2304.

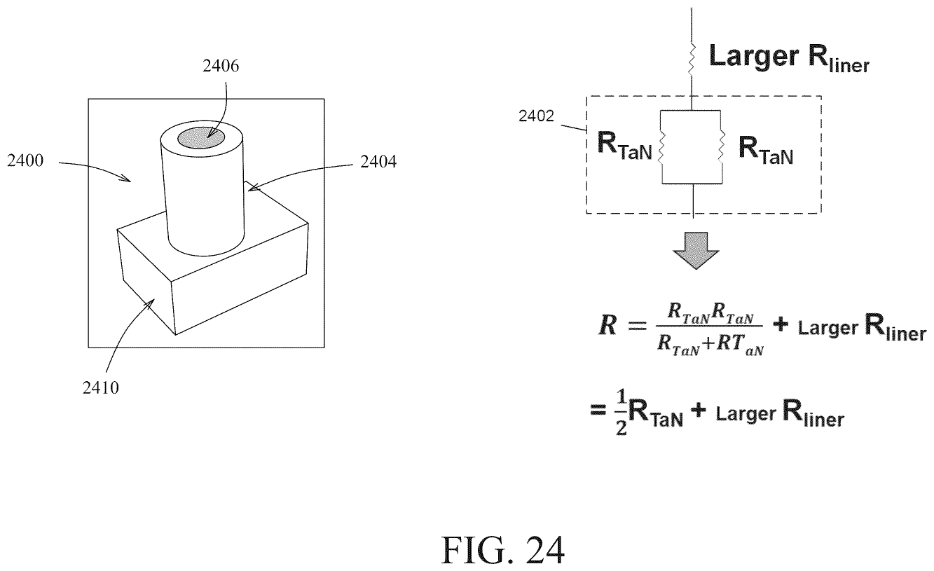

FIG. 24 depicts a perspective view of an exemplary BEVA heating structure 2400 having a substantially cylindrical shape with a substantially annular, circular or ringlike cross-section of vertical sidewall portions 2404 of conductive barrier material overlying a bottom electrode 2410 with an exposed interior portion 2406 or insulating material corresponding to the fabrication process of FIGS. 13-15 without formation of the conductive barrier liner layer 500 underlying the PCM structure 1502 and a corresponding equivalent resistance of the resulting BEVA heating structure 2400. By reducing the lateral surface area and effective width of the remaining portions of the conductive barrier layer 300 underlying the PCM structure 1502, the ratio of the length to width and thereby the effective resistance between the conductive structure 800 and the vertical sidewall portions 2404 is increased relative to the embodiment of FIG. 23, thereby increasing the resistance of the PCM memory cell structure 1500 relative to the PCM memory cell structure 1000, as described above.

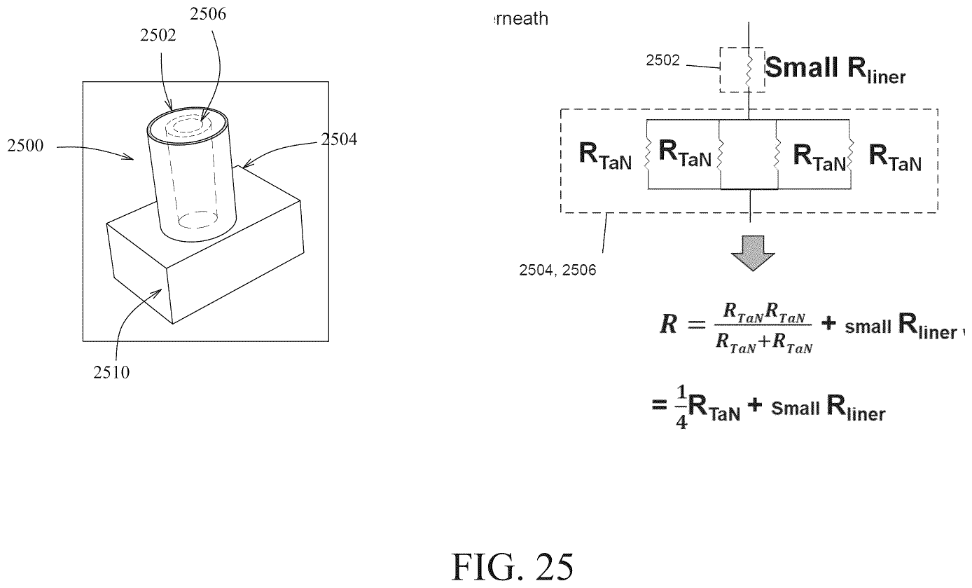

FIG. 25 depicts a perspective view of an exemplary BEVA heating structure 2500 having a substantially cylindrical shape with peripheral and interior vertical sidewall portions 2504, 2506 of conductive barrier material having substantially annular, circular or ringlike cross-sections overlying a bottom electrode 2510 with a substantially planar top liner portion 2502 of conductive barrier material (e.g., conductive barrier layer 500) corresponding to the fabrication process of FIGS. 16-21 and a corresponding equivalent resistance of the resulting BEVA heating structure 2500. The interior conductive ring portions 2506 provide an electrical resistance substantially parallel to the peripheral conductive ring portions 2504 to decrease the equivalent resistance of the resulting BEVA heating structure 2500 relative to the BEVA heating structure 2300 from an electrical perspective but results in more uniform heat distribution or improved thermal efficiency.

In one aspect, a memory cell structure is provided that includes a bottom electrode, an enclosing portion of conductive material disposed within an interlayer dielectric layer, the enclosing portion of conductive material overlying the bottom electrode and laterally circumscribing a region of insulating material overlying the bottom electrode, a phase change material layer overlying the enclosing portion of conductive material and the region of insulating material, wherein the region of insulating material is disposed between the bottom electrode and the phase change material layer, a top electrode overlying the phase change material layer, and a conductive structure between the top electrode and the enclosing portion of conductive material to provide a conductive path between the top electrode and the bottom electrode through the enclosing portion of conductive material and the conductive structure.

In one aspect, the memory cell structure includes a conductive barrier layer overlying the enclosing portion of conductive material and the region of insulating material, wherein the conductive structure contacts the conductive barrier layer to provide the conductive path through the conductive barrier layer.

In one aspect, the conductive structure includes a sidewall spacer of a conductive barrier material laterally adjacent to at least a portion of the phase change material layer.

In one aspect, the memory cell structure includes a second enclosing portion of conductive material disposed within the interlayer dielectric layer, the second enclosing portion of conductive material overlying the bottom electrode and laterally circumscribing a second region of insulating material overlying the bottom electrode, wherein the phase change material layer overlies the second enclosing portion of conductive material and the second region of insulating material and at least a portion of the second enclosing portion of conductive material contacts the enclosing portion of conductive material to provide the conductive path through the enclosing portion of conductive material and the second enclosing portion of conductive material.

In one aspect, the memory cell structure includes a conductive barrier layer overlying the enclosing portion of conductive material and the second enclosing portion of conductive material, wherein the conductive structure contacts the conductive barrier layer to provide the conductive path through the conductive barrier layer and the conductive barrier layer contacts the enclosing portion of conductive material and the second enclosing portion of conductive material to provide a first conductive path through the enclosing portion of conductive material electrically parallel to a second conductive path through the second enclosing portion of conductive material.

In one aspect, the enclosing portion of conductive material includes a portion of a barrier layer of tantalum nitride overlying and contacting the bottom electrode.

In one aspect, the region of insulating material includes a low-k dielectric material overlying at least a portion of the barrier layer of tantalum nitride.

In one aspect, the phase change material layer is one of Ge₂Sb₂Te₅ (GST), Ge—In—Sb—Te (GIST) and Ag—In—Sb—Te (AIST).

In another aspect, a method is provided for fabricating a memory cell of a semiconductor device. The method involves forming a voided region within an interlayer dielectric layer overlying at least a portion of a bottom electrode of conductive material on a semiconductor substrate, forming a conductive barrier layer overlying the interlayer dielectric layer and the portion of the bottom electrode within the voided region, forming an insulating layer overlying the conductive barrier layer, resulting in a region of the insulating layer laterally circumscribed by an enclosing portion of the conductive barrier layer within the voided region within the interlayer dielectric layer, forming a phase change material structure overlying the enclosing portion of the conductive barrier layer and the region of the insulating layer, and forming a conductive structure providing a conductive path between a top electrode of the phase change material structure and the bottom electrode through the conductive structure and the enclosing portion of the conductive barrier layer.

In one aspect, forming the insulating layer involves conformally depositing the insulating layer overlying the conductive barrier layer and planarizing the insulating layer to remove portions of the insulating layer from the conductive barrier layer overlying the interlayer dielectric layer to obtain the region of the insulating layer disposed within the voided region within the interlayer dielectric layer and laterally circumscribed by the enclosing portion of the conductive barrier layer.

In one aspect, planarizing the insulating layer involves planarizing the insulating layer until reaching the conductive barrier layer.

In one aspect, planarizing the insulating layer involves planarizing the insulating layer until reaching the interlayer dielectric layer to remove portions of the conductive barrier layer overlying the interlayer dielectric layer.

In one aspect, the method involves forming a second conductive barrier layer overlying the interlayer dielectric layer, the enclosing portion of the conductive barrier layer and the region of the insulating layer after planarizing the insulating layer, wherein forming the conductive structure involves forming the conductive structure contacting the second conductive barrier layer to provide the conductive path through the second conductive barrier layer.

In one aspect, forming the conductive structure involves forming a sidewall spacer of a conductive barrier material overlying the second conductive barrier layer laterally adjacent to at least a portion of the top electrode and a phase change material layer of the phase change material structure to provide the conductive path between the top electrode and the enclosing portion through the sidewall spacer.

In one aspect, forming the conductive structure involves forming a sidewall spacer of a conductive barrier material laterally adjacent to at least a portion of the top electrode and a phase change material layer of the phase change material structure to provide the conductive path between the top electrode and the enclosing portion through the sidewall spacer.

In one aspect, a semiconductor device is provided that includes a first interconnect layer comprising a bottom electrode of conductive material, a bottom electrode via (BEVA) structure overlying the bottom electrode within a first interlayer dielectric layer overlying the first interconnect layer, wherein the BEVA structure includes a bottom portion of a conductive barrier material overlying and contacting at least a portion of the bottom electrode underlying a voided region in the first interlayer dielectric layer, an enclosing portion of the conductive barrier material within the voided region overlying the bottom portion of the conductive barrier material, and an interior portion of an insulating material overlying the bottom portion of the conductive barrier material, wherein the enclosing portion laterally circumscribes the interior portion, a phase change material (PCM) structure overlying the BEVA structure, the PCM structure comprising a PCM layer overlying the BEVA structure and a top electrode layer overlying the PCM layer, wherein the PCM structure is configured to provide a conductive path between the top electrode layer and the enclosing portion, a top electrode via (TEVA) structure overlying the PCM structure, and a second interconnect layer including a top electrode of conductive material overlying the TEVA structure, wherein the TEVA structure provides a second conductive path between the top electrode and the top electrode layer.

In one aspect, the conductive barrier material is tantalum nitride or otherwise includes tantalum and nitride.

In one aspect, the PCM structure includes a conductive barrier material layer disposed between the PCM layer and the first interlayer dielectric layer, wherein the conductive barrier material layer contacts the enclosing portion to provide the conductive path through the conductive barrier material layer.

In one aspect, the conductive barrier material layer overlies the interior portion of the insulating material.

In one aspect, the PCM structure comprises a conductive spacer laterally adjacent to the PCM layer and contacting the top electrode layer to provide the conductive path between the top electrode layer and the enclosing portion.

While at least one exemplary embodiment has been presented in the foregoing detailed description of the disclosure, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing an exemplary embodiment of the disclosure. It being understood that various changes may be made in the function and arrangement of elements described in an exemplary embodiment without departing from the scope of the disclosure as set forth in the appended claims.

What is claimed is:

1. A memory cell structure comprising:
a bottom electrode;
an enclosing portion of conductive material disposed within an interlayer dielectric layer, the enclosing portion of conductive material overlying the bottom electrode and laterally circumscribing a region of insulating material overlying the bottom electrode;
a phase change material layer overlying the enclosing portion of conductive material and the region of insulating material, wherein the region of insulating material is disposed between the bottom electrode and the phase change material layer;
a top electrode overlying the phase change material layer; and
a conductive structure between the top electrode and the enclosing portion of conductive material to provide a conductive path between the top electrode and the bottom electrode through the enclosing portion of conductive material and the conductive structure.

2. The memory cell structure of claim 1, further comprising a conductive barrier layer overlying the enclosing portion of conductive material and the region of insulating material, wherein the conductive structure contacts the conductive barrier layer to provide the conductive path through the conductive barrier layer.

3. The memory cell structure of claim 1, wherein the conductive structure comprises a sidewall spacer of a conductive barrier material laterally adjacent to at least a portion of the phase change material layer.

4. The memory cell structure of claim 1, further comprising a second enclosing portion of conductive material disposed within the interlayer dielectric layer, the second enclosing portion of conductive material overlying the bottom electrode and laterally circumscribing a second region of insulating material overlying the bottom electrode, wherein:
the phase change material layer overlies the second enclosing portion of conductive material and the second region of insulating material; and
at least a portion of the second enclosing portion of conductive material contacts the enclosing portion of conductive material to provide the conductive path through the enclosing portion of conductive material and the second enclosing portion of conductive material.

5. The memory cell structure of claim 4, further comprising a conductive barrier layer overlying the enclosing portion of conductive material and the second enclosing portion of conductive material, wherein:
the conductive structure contacts the conductive barrier layer to provide the conductive path through the conductive barrier layer; and
the conductive barrier layer contacts the enclosing portion of conductive material and the second enclosing portion of conductive material to provide a first conductive path through the enclosing portion of conductive material electrically parallel to a second conductive path through the second enclosing portion of conductive material.

6. The memory cell structure of claim 1, wherein the enclosing portion of conductive material comprises a portion of a barrier layer of tantalum nitride overlying and contacting the bottom electrode.

7. The memory cell structure of claim 6, wherein the region of insulating material comprises a low-k dielectric material overlying at least a portion of the barrier layer of tantalum nitride.

8. The memory cell structure of claim 7, wherein the phase change material layer comprises one of Ge₂Sb₂Te₅(GST), Ge—In—Sb—Te (GIST) and Ag—In—Sb—Te (AIST).

9. A method of fabricating a memory cell of a semiconductor device, the method comprising:
forming a voided region within an interlayer dielectric layer overlying at least a portion of a bottom electrode of conductive material on a semiconductor substrate;
forming a conductive barrier layer overlying the interlayer dielectric layer and the portion of the bottom electrode within the voided region;
forming an insulating layer overlying the conductive barrier layer, resulting in a region of the insulating layer laterally circumscribed by an enclosing portion of the conductive barrier layer within the voided region within the interlayer dielectric layer;
forming a phase change material structure overlying the enclosing portion of the conductive barrier layer and the region of the insulating layer; and
forming a conductive structure providing a conductive path between a top electrode of the phase change material structure and the bottom electrode through the conductive structure and the enclosing portion of the conductive barrier layer.

10. The method of claim 9, wherein forming the insulating layer comprises:
conformally depositing the insulating layer overlying the conductive barrier layer; and
planarizing the insulating layer to remove portions of the insulating layer from the conductive barrier layer overlying the interlayer dielectric layer to obtain the region of the insulating layer disposed within the voided region within the interlayer dielectric layer and laterally circumscribed by the enclosing portion of the conductive barrier layer.

11. The method of claim 10, wherein planarizing the insulating layer comprises planarizing the insulating layer until reaching the conductive barrier layer.

12. The method of claim 10, wherein planarizing the insulating layer comprises planarizing the insulating layer until reaching the interlayer dielectric layer to remove portions of the conductive barrier layer overlying the interlayer dielectric layer.

13. The method of claim 12, further comprising forming a second conductive barrier layer overlying the interlayer dielectric layer, the enclosing portion of the conductive barrier layer and the region of the insulating layer after planarizing the insulating layer, wherein forming the conductive structure comprises forming the conductive structure contacting the second conductive barrier layer to provide the conductive path through the second conductive barrier layer.

14. The method of claim 13, wherein forming the conductive structure comprises forming a sidewall spacer of a conductive barrier material overlying the second conductive barrier layer laterally adjacent to at least a portion of the top electrode and a phase change material layer of the phase change material structure to provide the conductive path between the top electrode and the enclosing portion through the sidewall spacer.

15. The method of claim 9, wherein forming the conductive structure comprises forming a sidewall spacer of a conductive barrier material laterally adjacent to at least a portion of the top electrode and a phase change material layer of the phase change material structure to provide the conductive path between the top electrode and the enclosing portion through the sidewall spacer.

16. A semiconductor device comprising:
a first interconnect layer comprising a bottom electrode of conductive material;
a bottom electrode via (BEVA) structure overlying the bottom electrode within a first interlayer dielectric layer overlying the first interconnect layer, wherein the BEVA structure comprises:
a bottom portion of a conductive barrier material overlying and contacting at least a portion of the bottom electrode underlying a voided region in the first interlayer dielectric layer;
an enclosing portion of the conductive barrier material within the voided region overlying the bottom portion of the conductive barrier material; and
an interior portion of an insulating material overlying the bottom portion of the conductive barrier material, wherein the enclosing portion laterally circumscribes the interior portion;
a phase change material (PCM) structure overlying the BEVA structure, the PCM structure comprising a PCM layer overlying the BEVA structure and a top electrode layer overlying the PCM layer, wherein the PCM structure is configured to provide a conductive path between the top electrode layer and the enclosing portion;
a top electrode via (TEVA) structure overlying the PCM structure; and
a second interconnect layer comprising a top electrode of conductive material overlying the TEVA structure, wherein the TEVA structure provides a second conductive path between the top electrode and the top electrode layer.

17. The semiconductor device of claim 16, wherein the conductive barrier material comprises tantalum and nitride.

18. The semiconductor device of claim 16, wherein the PCM structure comprises a conductive barrier material layer disposed between the PCM layer and the first interlayer dielectric layer, wherein the conductive barrier material layer contacts the enclosing portion to provide the conductive path through the conductive barrier material layer.

19. The semiconductor device of claim 18, wherein the conductive barrier material layer overlies the interior portion of the insulating material.

20. The semiconductor device of claim 16, wherein the PCM structure comprises a conductive spacer laterally adjacent to the PCM layer and contacting the top electrode layer to provide the conductive path between the top electrode layer and the enclosing portion.
